(19) United States
(12) Patent Application Publication
(10) Pub. No.: US 2011/0017177 A1
(43) Pub. Date: Jan. 27, 2011

(54) Monolithic piezoactuator with transition region and safety layer, and use of the piezoactuator

(76) Inventors: Masahiro Inagaki, Kagoshima (JP); Harald Johannes Kastl, Fichtelberg (DE); Takami Sakamoto, Kagoshima (JP); Carsten Schuh, Baldham (DE)

Correspondence Address: King & Spalding LLP, 401 Congress Avenue, Suite 3200, Austin, TX, 78701, US

(21) Appl. No.: 12/445,955

(22) PCT Filed: Oct. 23, 2007
(86) PCT No.: PCT/EP07/61309

§ 371 Date: Sep. 28, 2010

(30) Foreign Application Priority Data
Oct. 23, 2006 (DE) 102006049892.5

(51) Int. Cl. F02M 51/00; H01L 41/083; H02N 2/04; H01S 4/00

(52) U.S. Cl. 123/494; 310/367; 29/592.1

(57) ABSTRACT

A piezoactuator of monolithic multilayer design with an overall stack has at least one piezoelectrically active partial stack with piezoceramic layers arranged one above another and electrode layers arranged between these layers, at least one piezoelectrically inactive terminating region arranged above the partial stack, and at least one transition region arranged between the partial stack and the terminating region. The transition region has piezoceramic layers arranged one above another and electrode layers arranged between the piezoceramic layers and the piezoceramic layers and the electrode layers are arranged on one another such that there the electric fields that can be coupled into the piezoceramic layers are changed by electrical driving of the electrode layers successively in the transition region stack direction from piezoceramic layer to piezoceramic layer, and the partial stack has a safety layer towards the transition region, wherein a crack is preferably formed in the case of mechanical overloading.

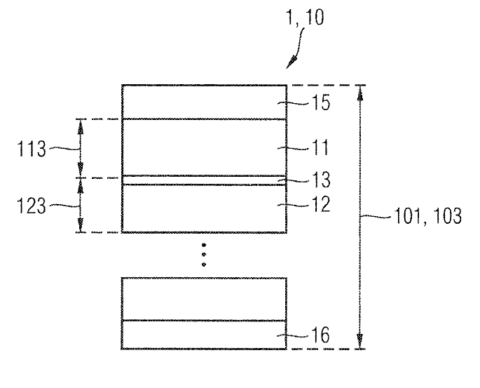

### CROSS-REFERENCE TO RELATED APPLICATIONS

This application is a United States national phase filing under 35 U.S.C. §371 of International Application No. PCT/EP2007/061309, filed Oct. 23, 2007 which claims priority to German Patent Application No. 10 2006 049 892.5, filed Oct. 23, 2006. The complete disclosure of the above-identified application is hereby fully incorporated herein by reference.

### TECHNICAL FIELD

The invention relates to a piezoactuator of monolithic multilayer design.

### BACKGROUND

When such piezoactuators are initially driven electrically up to the large-signal range (field strengths of several kV/mm), the piezoceramic material is polarized. The result is an irreversible change in length, referred to as residual extension. Due to the residual extension and due to an additional extension which occurs upon electrical driving of the electrode layers when the piezoactuator is operated, tensile stresses arise in the overall stack. These tensile stresses lead to cracks (polarization cracks) arising along a boundary surface between a piezoceramic layer and an electrode layer in the course of polarization or during operation of the piezoactuator. Such cracks occur in particular in the transition region between active partial stack and terminating region. Branching cracks or cracks which spread in the longitudinal direction of the overall stack are especially damaging. Such cracks inevitably lead to premature failure of the piezoactuator.

### SUMMARY

According to various embodiments, a piezoactuator can be specified in which the likelihood that cracks as described above will form and grow is diminished in comparison to the prior art.

According to an embodiment, a piezoactuator of monolithic multilayer design with an overall stack may comprise at least one piezoelectrically active partial stack, wherein the partial stack has piezoceramic layers arranged one above another and electrode layers arranged between the piezoceramic layers, at least one piezoelectrically inactive terminating region arranged above the piezoelectrically active partial stack, and at least one transition region arranged between the piezoelectrically active partial stack and the terminating region, wherein the transition region has transition-region piezoceramic layers arranged one above another and transition-region electrode layers arranged between the transition-region piezoceramic layers, and the transition-region piezoceramic layers and the transition-region electrode layers are configured and arranged on one another in such a way that there is a change in the electric fields that can be coupled into the transition-region piezoceramic layers by electrical driving of the transition-region electrode layers successively in the stack direction of the transition region from transition-region piezoceramic layer to transition-region piezoceramic layer, and the piezoelectrically active partial stack has a safety layer towards the transition region, in which safety layer a crack is preferably formed in the case of mechanical overloading.

According to a further embodiment, the stack direction of the transition region may extend from the electrically active partial stack towards the terminating region, and a layer thickness of the transition-region electrode layers may increase successively from transition-region electrode layer to transition-region electrode layer. According to a further embodiment, the layer thicknesses of the transition-region piezoceramic layers may increase, starting from a layer thickness unit, by the following factors: 1.2; 1.5; 2.0; 2.8; 3.8. According to a further embodiment, at least one of the transition-region piezoceramic layers may have individual piezoceramic layers arranged one above another. According to a further embodiment, the thickness-layer unit of the transition-region electrode layers may correspond to a thickness layer of a piezoceramic layer of the piezoelectrically active partial stack. According to a further embodiment, a maximum of ten piezoceramic layers, and in particular a maximum of 5 piezoceramic layers, can be arranged between the safety layer of the piezoelectrically active partial stack and of the transition region. According to a further embodiment, the safety layer can be formed by one of the electrode layers of the piezoelectrically active partial stack and/or by a boundary surface between one of the electrode layers and an adjacent piezoceramic layer of the piezoelectrically active partial stack. According to a further embodiment, the piezoelectrically active partial stack and/or the terminating region may have a partial-stack height selected from the range from 1 mm inclusive to 10 mm inclusive and in particular from the range from 3 mm inclusive to 5 mm inclusive. According to a further embodiment, the transition region may have a transition-region partial stack with a transition-stack height selected from the range from 0.2 mm inclusive to 5.0 mm inclusive and in particular from the range from 0.5 mm inclusive to 2.0 mm inclusive. According to a further embodiment, the overall stack may have an overall-stack height which is selected from the range from 10 mm inclusive to 200 mm inclusive.

According to yet another embodiment, such a piezoactuator as described above can be used for controlling a valve and in particular an injection valve of an internal combustion engine.

### BRIEF DESCRIPTION OF THE DRAWINGS

The invention will be described in detail below with the aid of several exemplary embodiments and the associated figures. The figures are schematic and do not constitute scale diagrams.

The FIGURE shows a side view of a piezoactuator of a monolithic multilayer design.

### DETAILED DESCRIPTION

According to various embodiments, a piezoactuator of monolithic multilayer design with an overall stack is specified, comprising at least one piezoelectrically active partial stack, wherein the partial stack has piezoceramic layers arranged one above another and electrode layers arranged between the piezoceramic layers, at least one piezoelectrically inactive terminating region arranged above the piezoelectrically active partial stack and at least one transition region arranged between the piezoelectrically active partial stack and the terminating region, the transition region having transition-region piezoceramic layers arranged one above another and transition-region electrode layers arranged between the transition-region piezoceramic layers, and the transition-region piezoceramic layers and the transition-region electrode layers being configured and arranged on one another in such a way that there is a change in the electric fields that can be coupled into the transition-region piezoceramic layers by electrical driving of the transition-region electrode layers successively in the stack direction of the transition region from transition-region piezoceramic layer to transition-region piezoceramic layer, and the piezoelectrically active partial stack having a safety layer towards the transition region, in which safety layer a crack is preferably formed in the case of mechanical overloading.

The stack direction of the transition region preferably extends from the electrically active partial stack towards the terminating region. A layer thickness of the transition-region electrode layers increases successively from transition-region electrode layer to transition-region electrode layer.

The terminating region can be a top or bottom region of the overall stack. The terminating region can consist of one layer or of a plurality of layers. In the latter case, it is referred to as a covering packet. Ceramic or metallic materials may be considered for use as material for the terminating region.

A piezoceramic material of the piezoceramic layers and a piezoceramic material of the transition-region piezoceramic layers can be identical. Different materials can, however, also be used.

According to various embodiments a transition region is provided with gradation in terms of deflection of the piezoceramic. The gradation results in the deflection of the piezoceramic upon electrical driving of the transition-region electrode layers changing successively from transition-region piezoceramic layer to transition-region piezoceramic layer. The deflection is reduced from the active partial stack towards the inactive terminating region. Adaptation of the deflection takes place. In this way, the internal mechanical stresses are reduced due to the differing deflections. At the same time, a safety layer is arranged in the vicinity. This safety layer functions as a pressure-relief joint. The safety layer forms the weakest element in the monolithic overall stack. A crack is formed upon mechanical overloading (induced internally or from the outside) preferably in or on the safety layer. It has been shown that the combination of gradation in the transition region and safety layer in the piezoelectrically active partial stack leads to significantly enhanced reliability of the piezoactuator.

The increase in layer thicknesses can be chosen randomly. The layer thicknesses of the transition-region piezoceramic layers advantageously increase, starting from a layer-thickness unit, by the following factors: 1.2; 1.5; 2.0; 2.8; 3.8. An alternative series is defined for example by the following factors: 1.1; 1.3; 1.6; 2.0; 2.5; 3.1; for example as follows: the layer-thickness unit is, for example, 80 μm.

The transition-region piezoceramic layers can comprise one layer in each case, making them monolayer. However, it is advantageous if the transition-region piezoceramic layers are multilayer. At least one of the transition-region piezoceramic layers has to this end individual piezoceramic layers arranged one above another. During manufacture, the multilayer transition-region piezoceramic layer is constructed from a plurality of piezoceramic green films.

The layer-thickness unit of the transition-region electrode layers corresponds in particular to a layer thickness of a piezoceramic layer of the piezoelectrically active partial stack. This means, for example, that the transition-region piezoceramic layer immediately adjacent to the piezoelectrically active partial stack has the layer thickness of the adjacent piezoceramic layer of the piezoelectrically active partial stack.

It has proven to be particularly advantageous to provide that a maximum of ten piezoceramic layers and in particular a maximum of 5 piezoceramic layers be arranged between the safety layer of the piezoelectrically active partial stack and of the transition region. It is provided for this purpose that the safety layer be arranged in the vicinity of the transition region.

The safety layer can be formed by a piezoceramic layer of the active partial stack. In particular, the safety layer is formed by one of the electrode layers of the piezoelectrically active partial stack and/or by a boundary surface between one of the electrode layers and an adjacent piezoceramic layer of the piezoelectrically active partial stack.

According to an embodiment, the active partial stack and/or the terminating region has a partial-stack height selected from the range from 1 mm inclusive to 10 mm inclusive and in particular from the range from 3 mm inclusive to 5 mm inclusive. The partial-stack height is, for example, 2 mm. It has been shown that with these partial-stack heights peak stresses can be reduced very well. According to an embodiment, the transition-region partial stack has a transition-stack height selected from the range from 0.2 mm inclusive to 5.0 mm inclusive and in particular from the range from 0.5 mm inclusive to 2.0 mm inclusive. With the partial stacks, very high overall stacks are available. In an embodiment, the overall stack has an overall-stack height which is selected from the range from 10 mm inclusive to 200 mm inclusive. Higher overall-stack heights are also available.

Further measures to reduce the mechanical stresses occurring in the overall stack when it is electrically driven can additionally be undertaken. These measures relate, for example, to integration of electrically inactive electrode layers in the terminating region. The electrically inactive electrode layers are not driven electrically during polarization and during operation of the piezoactuator.

This new reliable piezoactuator is preferably used for controlling a valve and in particular an injection valve of an internal combustion engine. The internal combustion engine is, for example, an engine of a motor vehicle.

The piezoactuator 1 is a piezoactuator with an overall stack 10 of a monolithic multilayer design. The piezoactuator 1 has a piezoelectrically active partial stack 12 with piezoceramic layers with lead zirconate titanate (PZT) as piezoceramic material and electrode layers made of a silver-palladium alloy arranged in an alternating manner above one another.

A piezoelectrically inactive terminating region 15 in the form of a ceramic covering packet made of ceramic layers is arranged above the piezoelectrically active partial stack 12.

A transition region 12 in the form of a transition-region stack is arranged between the piezoelectrically active partial stack 11 and the covering packet 15. The transition-region stack 12 has transition-region piezoceramic layers and transition-region electrode layers arranged in an alternating manner above one another. The piezoceramic material of the transition-region piezoceramic layers and the piezoceramic material of the piezoceramic layers of the piezoelectrically active partial stack are identical. In an alternative embodiment, the piezoceramic materials are different. The electrode material of the transition-region electrode layers corresponds to that of the electrode layers of the piezoelectrically active partial stack. Alternatively, different electrode materials are used.

The piezoelectrically active partial stack, the transition-region stack and the terminating region together form a monolithic overall stack 10. External metallizations (not shown) for electrically contacting the respective electrode layers are applied to lateral surfaces of the overall stack in the area of the active partial stack and in the area of the transition-region stack.

The overall height 103 of the overall stack 10 in the direction of the stack 101 is 30 mm. The partial-stack height 123 of the piezoelectrically active partial stack 12 is approximately 10 mm. The transition-region partial-stack height 113 of the transition-region stack 11 is approximately 2 mm.

Inside the transition-region partial stack, the layer thicknesses of the transition-region piezoceramic layers increase in the stack direction from the active partial stack toward the terminating region.

In addition, a safety layer 13 is arranged inside the active partial stack 12 in proximity to the transition region 11. The safety layer 13 is formed by an electrode layer.

Further exemplary embodiments emerge in that, not only or as an alternative to the arrangement shown, a terminating region 16 with associated transition region is provided in the bottom region of the overall stack.

This new piezoactuator 1 is used for controlling an injection valve of an engine of a motor vehicle.

1. A piezoactuator of monolithic multilayer design with an overall stack comprising
at least one piezoelectrically active partial stack, wherein the partial stack has piezoceramic layers arranged one above another and electrode layers arranged between the piezoceramic layers,
at least one piezoelectrically inactive terminating region arranged above the piezoelectrically active partial stack, and
at least one transition region arranged between the piezoelectrically active partial stack and the terminating region, wherein
the transition region has transition-region piezoceramic layers arranged one above another and transition-region electrode layers arranged between the transition-region piezoceramic layers, and
the transition-region piezoceramic layers and the transition-region electrode layers are configured and arranged on one another in such a way that there is a change in the electric fields that can be coupled into the transition-region piezoceramic layers by electrical driving of the transition-region electrode layers successively in the stack direction of the transition region from transition-region piezoceramic layer to transition-region piezoceramic layer, and
the piezoelectrically active partial stack has a safety layer towards the transition region, in which safety layer a crack is preferably formed in the case of mechanical overloading.

2. The piezoactuator as claimed in claim 1,
wherein the stack direction of the transition region extends from the electrically active partial stack towards the terminating region, and a layer thickness of the transition-region electrode layers increases successively from transition-region electrode layer to transition-region electrode layer.

3. The piezoactuator as claimed in claim 2,
wherein the layer thicknesses of the transition-region piezoceramic layers increase, starting from a layer thickness unit, by the following factors: 1.2; 1.5; 2.0; 2.8; 3.8.

4. The piezoactuator as claimed in claim 1,
wherein at least one of the transition-region piezoceramic layers has individual piezoceramic layers arranged one above another.

5. The piezoactuator as claimed in claim 1,
wherein the thickness-layer unit of the transition-region electrode layers corresponds to a thickness layer of a piezoceramic layer of the piezoelectrically active partial stack.

6. The piezoactuator as claimed in claim 1,
wherein a maximum of ten piezoceramic layers, are arranged between the safety layer of the piezoelectrically active partial stack and of the transition region.

7. The piezoactuator as claimed in claim 1,
wherein the safety layer is formed by one of the electrode layers of the piezoelectrically active partial stack and/or by a boundary surface between one of the electrode layers and an adjacent piezoceramic layer of the piezoelectrically active partial stack.

8. The piezoactuator as claimed in claim 1,
wherein at least one of the piezoelectrically active partial stack and the terminating region has a partial-stack height selected from the range from 1 mm inclusive to 10 mm inclusive.

9. The piezoactuator as claimed in claim 1,
wherein the transition region has a transition-region partial stack with a transition-stack height selected from the range from 0.2 mm inclusive to 5.0 mm inclusive.

10. The piezoactuator as claimed in claim 1,
wherein the overall stack has an overall-stack height which is selected from the range from 10 mm inclusive to 200 mm inclusive.

11. A method comprising the step of using a piezoactuator for controlling a valve or an injection valve of an internal combustion engine, wherein the piezoactuator is of monolithic multilayer design with an overall stack comprising
at least one piezoelectrically active partial stack, wherein the partial stack has piezoceramic layers arranged one above another and electrode layers arranged between the piezoceramic layers,
at least one piezoelectrically inactive terminating region arranged above the piezoelectrically active partial stack, and
at least one transition region arranged between the piezoelectrically active partial stack and the terminating region, wherein
the transition region has transition-region piezoceramic layers arranged one above another and transition-region electrode layers arranged between the transition-region piezoceramic layers, and
the transition-region piezoceramic layers and the transition-region electrode layers are configured and arranged on one another in such a way that there is a change in the electric fields that can be coupled into the transition-region piezoceramic layers by electrical driving of the transition-region electrode layers successively in the stack direction of the transition region from transition-region piezoceramic layer to transition-region piezoceramic layer, and
the piezoelectrically active partial stack has a safety layer towards the transition region, in which safety layer a crack is preferably formed in the case of mechanical overloading.

12. The piezoactuator as claimed in claim 1, wherein a maximum of 5 piezoceramic layers are arranged between the safety layer of the piezoelectrically active partial stack and of the transition region.

13. The piezoactuator as claimed in claim 1, wherein at least one of the piezoelectrically active partial stack and the terminating region has a partial-stack height selected from the range from 3 mm inclusive to 5 mm inclusive.

14. The piezoactuator as claimed in claim 1, wherein the transition region has a transition-region partial stack with a transition-stack height selected from the range from 0.5 mm inclusive to 2.0 mm inclusive.

15. A method of providing a piezoactuator of monolithic multilayer design with an overall stack comprising the steps of:
providing at least one piezoelectrically active partial stack by arranging piezoceramic layers one above another and arranging electrode layers between the piezoceramic layers,
arranging at least one piezoelectrically inactive terminating region above the piezoelectrically active partial stack, and
arranging at least one transition region between the piezoelectrically active partial stack and the terminating region, wherein
the transition region has transition-region piezoceramic layers arranged one above another and transition-region electrode layers arranged between the transition-region piezoceramic layers, and
the transition-region piezoceramic layers and the transition-region electrode layers are configured and arranged on one another in such a way that there is a change in the electric fields that can be coupled into the transition-region piezoceramic layers by electrical driving of the transition-region electrode layers successively in the stack direction of the transition region from transition-region piezoceramic layer to transition-region piezoceramic layer, and
providing a safety layer towards the transition region, in which safety layer a crack is preferably formed in the case of mechanical overloading.

16. The method as claimed in claim 15,
comprising the step of extending the stack direction of the transition region from the electrically active partial stack towards the terminating region, wherein a layer thickness of the transition-region electrode layers increases successively from transition-region electrode layer to transition-region electrode layer.

17. The method as claimed in claim 15,
wherein the layer thicknesses of the transition-region piezoceramic layers increase, starting from a layer thickness unit, by the following factors: 1.2; 1.5; 2.0; 2.8; 3.8.

18. The method as claimed in claim 15,
comprising the step of arranging individual piezoceramic layers of at least one of the transition-region piezoceramic layers one above another.

19. The method as claimed in claim 15,
wherein the thickness-layer unit of the transition-region electrode layers corresponds to a thickness layer of a piezoceramic layer of the piezoelectrically active partial stack.

20. The method as claimed in claim 15,
wherein a maximum of five or ten piezoceramic layers are arranged between the safety layer of the piezoelectrically active partial stack and of the transition region.
